(19) United States
(12) Patent Application Publication
(10) Pub. No.: US 2019/0189477 A1
(43) Pub. Date: Jun. 20, 2019

(54) OPTOELECTRONIC SEMICONDUCTOR STAMP AND MANUFACTURING METHOD THEREOF, AND OPTOELECTRONIC SEMICONDUCTOR

(71) Applicant: Ultra Display Technology Corp., Taipei City (TW)

(72) Inventor: Hsien-Te CHEN, Taipei City (TW)

(21) Appl. No.: 16/224,277

(22) Filed: Dec. 18, 2018

Related U.S. Application Data
(60) Provisional application No. 62/607,520, filed on Dec. 19, 2017.

(51) Int. Cl. H01L 21/67; H01L 21/683

(52) U.S. Cl. CPC H01L 21/67132; H01L 2221/68322; H01L 2221/68363; H01L 21/6835

(57) ABSTRACT

An optoelectronic semiconductor stamp and a manufacturing method thereof, and an optoelectronic semiconductor device are disclosed. The manufacturing method comprises the following steps: pressing an optoelectronic semiconductor substrate to an UV tape, wherein the electrodes of a plurality of optoelectronic semiconductor components are adhered to the UV tape; removing the epitaxial substrate, wherein at least a part of the optoelectronic semiconductor components are adhered to the UV tape; decreasing adhesion of at least a part of the UV tape; and picking up at least a part of the optoelectronic semiconductor components corresponding to the part of the UV tape with reduced adhesion by a heat conductive substrate, wherein the part of the optoelectronic semiconductor components corresponding to the part of the UV tape with reduced adhesion is removed from the UV tape so as to obtain an optoelectronic semiconductor stamp.

### CROSS REFERENCE TO RELATED APPLICATIONS

The non-provisional patent application claims priority to U.S. provisional patent application with Ser. No. 62/607,520 filed on Dec. 19, 2017. This and all other extrinsic materials discussed herein are incorporated by reference in their entirety.

### BACKGROUND

### Technology Field

The present disclosure relates to a semiconductor stamp and, in particular, to an optoelectronic semiconductor stamp and manufacturing method thereof, and an optoelectronic semiconductor device made by the optoelectronic semiconductor stamp.

### Description of Related Art

Compared with the conventional LCD device, the LED array device made of LEDs (e.g. LED display device), the Mini LED array device made of Mini LEDs (e.g. Mini LED display device), or the Micro LED array device made of Micro LEDs (e.g. Micro LED display device) does not need additional backlight source, so they can be manufactured with a lighter weight and a thinner shape.

In the conventional manufacturing process of optoelectronic device containing LED (e.g. display device), the LEDs are usually manufactured in advance by epitaxy process, and then the half-cut process (electrical isolation), point measurement process, and full-cut process are performed to obtain individual LEDs. Next, the individual LEDs are transferred to a supporting substrate. Afterwards, the pick-up head is provided to pick up one or more LEDs from the supporting substrate and then transfer the picked LEDs to, for example, a matrix circuit substrate for the following processes.

However, the conventional manufacturing method of transferring the LED dies one by one needs relatively higher apparatus accuracy and cost, and the manufacturing processes are complex and difficult. Thus, it is hard to carry out the goal of batch transferring, and the manufacturing time and cost of optoelectronic device are relatively higher.

### SUMMARY

An objective of this disclosure is to provide a novel optoelectronic semiconductor stamp and manufacturing method thereof and an optoelectronic semiconductor device made by the optoelectronic semiconductor stamp. Compared with the conventional manufacturing method, the optoelectronic semiconductor device of this disclosure has the advantages of simple processes and short manufacturing time. Besides, this disclosure can achieve the goal of batch transferring, so that the optoelectronic semiconductor device can have shorter manufacturing time and lower cost.

This disclosure provides a manufacturing method of an optoelectronic semiconductor stamp, comprising steps of: providing an optoelectronic semiconductor substrate, wherein the optoelectronic semiconductor substrate comprises a plurality of optoelectronic semiconductor components separately disposed on an epitaxial substrate, and each of the optoelectronic semiconductor components comprises at least an electrode; pressing the optoelectronic semiconductor substrate to an UV tape, wherein the electrodes of the optoelectronic semiconductor components are adhered to the UV tape; removing the epitaxial substrate, wherein at least a part of the optoelectronic semiconductor components are adhered to the UV tape; decreasing adhesion of at least a part of the UV tape; and picking up at least a part of the optoelectronic semiconductor components corresponding to the part of the UV tape with reduced adhesion by a heat conductive substrate, wherein the part of the optoelectronic semiconductor components corresponding to the part of the UV tape with reduced adhesion is removed from the UV tape so as to obtain the optoelectronic semiconductor stamp, the heat conductive substrate comprises a buffer layer disposed on a heat conductive base, and the buffer layer adheres the optoelectronic semiconductor components corresponding to the part of the UV tape with reduced adhesion.

In one embodiment, before the step of removing the epitaxial substrate, the manufacturing method further comprises: providing a light to irradiate a connection junction between the epitaxial substrate and at least a part of the optoelectronic semiconductor components.

In one embodiment, the step of removing the epitaxial substrate is to remove the epitaxial substrate by an etching process or a polishing process.

In one embodiment, a first pitch is defined between adjacent two of the optoelectronic semiconductor components on the optoelectronic semiconductor substrate, a second pitch is defined between adjacent two of optoelectronic semiconductor components of the optoelectronic semiconductor stamp, and the second pitch is greater than or equal to the first pitch.

In one embodiment, the second pitch is n times of the first pitch, and n is an integer greater than or equal to 1.

In one embodiment, the thermal conductivity of the heat conductive substrate is greater than 1 W/mK.

This disclosure also provides an optoelectronic semiconductor stamp, which comprises a heat conductive substrate and a plurality of optoelectronic semiconductor components. The heat conductive substrate comprises a heat conductive base and a buffer layer, and the buffer layer is disposed on the heat conductive base. The optoelectronic semiconductor components are adhered to the heat conductive base through the buffer layer, and the optoelectronic semiconductor components are separately disposed on the heat conductive substrate. The optoelectronic semiconductor stamp is formed by transferring at least a part of optoelectronic semiconductor components from an optoelectronic semiconductor substrate to the heat conductive substrate.

This disclosure further provides an optoelectronic semiconductor device, which comprises a target substrate and a plurality of optoelectronic semiconductor components. The target substrate has a plurality of electrical conductive portions. The optoelectronic semiconductor components comprises a plurality of electrodes, and the electrodes are disposed corresponding to and electrically connected to the electrical conductive portions. The optoelectronic semiconductor device is formed by transferring any of the above-mentioned optoelectronic semiconductor stamps to the target substrate.

In one embodiment, after the optoelectronic semiconductor stamp is pressed on the target substrate, the heat conductive base is heated to electrically connect the electrodes of the optoelectronic semiconductor components and the corresponding electrical conductive portions by eutectic bonding, and then the heat conductive substrate is removed.

In one embodiment, after the optoelectronic semiconductor stamp is pressed on the target substrate, the electrodes of the optoelectronic semiconductor components are electrically connected with the corresponding electrical conductive portions by anisotropic conductive film (ACF), and then the heat conductive substrate is removed.

In one embodiment, after the optoelectronic semiconductor stamp is pressed on the target substrate, the heat conductive substrate is removed, and then the electrodes of the optoelectronic semiconductor components are electrically connected with the corresponding electrical conductive portions by eutectic bonding.

In one embodiment, after the optoelectronic semiconductor stamp is pressed on the target substrate, the heat conductive substrate is removed, and then the electrodes of the optoelectronic semiconductor components are electrically connected with the corresponding electrical conductive portions by anisotropic conductive film (ACF).

In one embodiment, the optoelectronic semiconductor components on the heat conductive substrate of the optoelectronic semiconductor stamp are arranged in a polygon.

In one embodiment, the optoelectronic semiconductor device is a LED display device, a light sensing device, or a laser array.

As mentioned above, in this disclosure, the manufacturing method of the optoelectronic semiconductor stamp comprises steps of: pressing the optoelectronic semiconductor substrate to an UV tape; removing the epitaxial substrate, so that at least a part of the optoelectronic semiconductor components are adhered to the UV tape; decreasing adhesion of at least a part of the UV tape; and picking up at least a part of the optoelectronic semiconductor components corresponding to the part of the UV tape with reduced adhesion by a heat conductive substrate. The part of the optoelectronic semiconductor components corresponding to the part of the UV tape with reduced adhesion is removed from the UV tape so as to obtain the optoelectronic semiconductor stamp. Then, at least one optoelectronic semiconductor stamp can be transferred to the target substrate, or a plurality of optoelectronic semiconductor stamps can be combined and transferred to the target substrate, thereby obtaining the optoelectronic semiconductor device. Compared with the conventional manufacturing processes of optoelectronic device made of LEDs, which is to perform the epitaxial process, the photolithograph process, and the cutting processes (including half-cut, point measurement and full-cut processes) to obtain the individual optoelectronic semiconductor components, this disclosure does not need to transfer the optoelectronic semiconductor components to the target substrate one by one. As a result, this disclosure has the advantages of simple processes and short manufacturing time. Besides, this disclosure can achieve the goal of batch transferring, so that the optoelectronic semiconductor device can have shorter manufacturing time and lower cost.

### BRIEF DESCRIPTION OF THE DRAWINGS

The disclosure will become more fully understood from the detailed description and accompanying drawings, which are given for illustration only, and thus are not limitative of the present disclosure, and wherein:

FIG. 1 is a flow chart showing a manufacturing method of an optoelectronic semiconductor stamp according to an embodiment of this disclosure;

FIGS. 2A to 2F are schematic diagrams showing the manufacturing procedures of an optoelectronic semiconductor stamp according to a first embodiment of this disclosure;

FIG. 2G is a schematic diagram showing another optoelectronic semiconductor stamp according to the embodiment of this disclosure;

FIGS. 3A and 3B are schematic diagrams showing the manufacturing procedure of an optoelectronic semiconductor device according to an embodiment of this disclosure;

FIGS. 4A and 4B are schematic diagrams showing the combined shapes of the optoelectronic semiconductor devices according to different embodiments of this disclosure;

FIGS. 5A to 5D are schematic diagrams showing the manufacturing procedures of an optoelectronic semiconductor stamp according to a second embodiment of this disclosure; and

FIGS. 6A to 6D are schematic diagrams showing the manufacturing procedures of an optoelectronic semiconductor stamp according to a third embodiment of this disclosure.

### DETAILED DESCRIPTION OF THE DISCLOSURE

The present disclosure will be apparent from the following detailed description, which proceeds with reference to the accompanying drawings, wherein the same references relate to the same elements. The figures of all embodiments of the disclosure are merely illustrative and do not represent true dimensions, proportions or quantities. In addition, the orientations “upper” and “lower” as used in the following embodiments are merely used to indicate relative positional relationships. Furthermore, when defining that a component is “on,” “above,” “below,” or “under” another component, it can be realized that the two components are directly contacted with each other, or that the two components are not directly contacted with each other and an additional component is disposed between the two components.

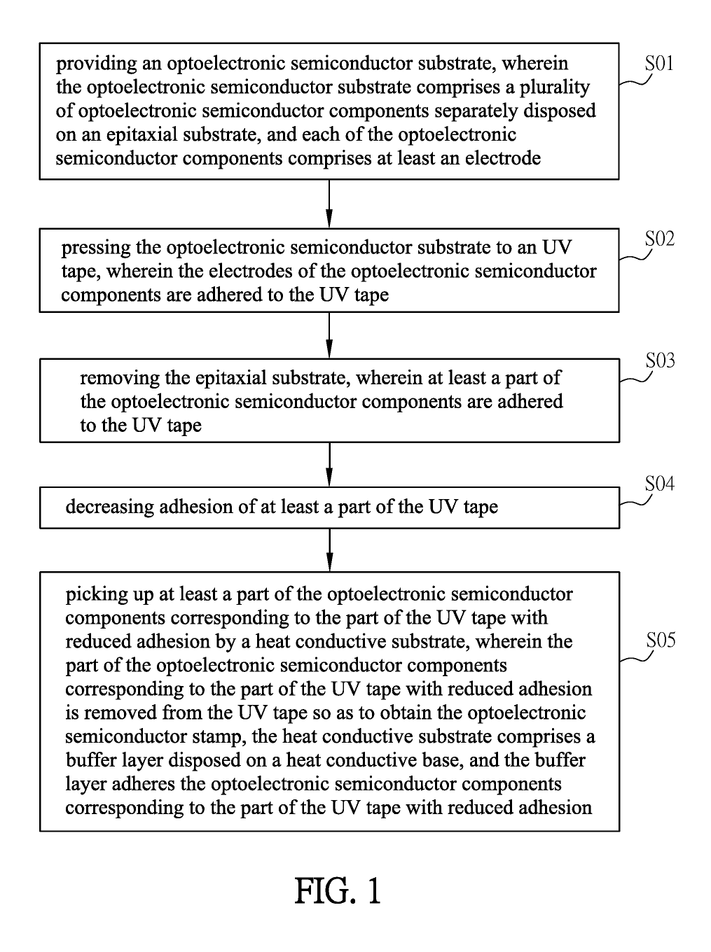

FIG. 1 is a flow chart showing a manufacturing method of an optoelectronic semiconductor stamp according to an embodiment of this disclosure. The optoelectronic semiconductor stamp made by the manufacturing method of this disclosure can be used to fabricate, for example but not limited to, display devices, advertising billboards, sensing devices, laser arrays, light-emitting devices or illumination devices, or other types or functions of optoelectronic semiconductor devices.

The manufacturing method of an optoelectronic semiconductor stamp of this disclosure comprises steps of: providing an optoelectronic semiconductor substrate, wherein the optoelectronic semiconductor substrate comprises a plurality of optoelectronic semiconductor components separately disposed on an epitaxial substrate, and each of the optoelectronic semiconductor components comprises at least an electrode (step S01); pressing the optoelectronic semiconductor substrate to an UV tape, wherein the electrodes of the optoelectronic semiconductor components are adhered to the UV tape (step S02); removing the epitaxial substrate, wherein at least a part of the optoelectronic semiconductor components are adhered to the UV tape (step S03); decreasing adhesion of at least a part of the UV tape (step S04); and picking up at least a part of the optoelectronic semiconductor components corresponding to the part of the UV tape with reduced adhesion by a heat conductive substrate, wherein the part of the optoelectronic semiconductor components corresponding to the part of the UV tape with reduced adhesion is removed from the UV tape so as to obtain the optoelectronic semiconductor stamp, the heat conductive substrate comprises a buffer layer disposed on a heat conductive base, and the buffer layer adheres the optoelectronic semiconductor components corresponding to the part of the UV tape with reduced adhesion (step S05).

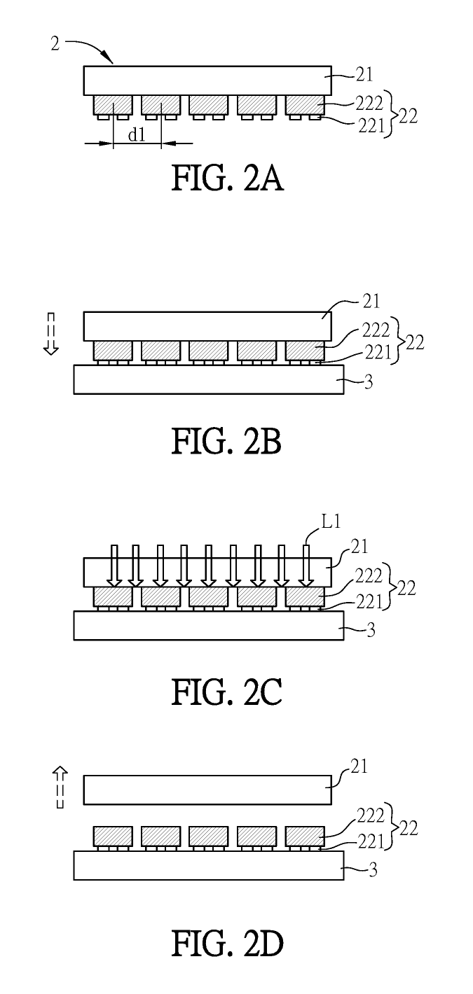

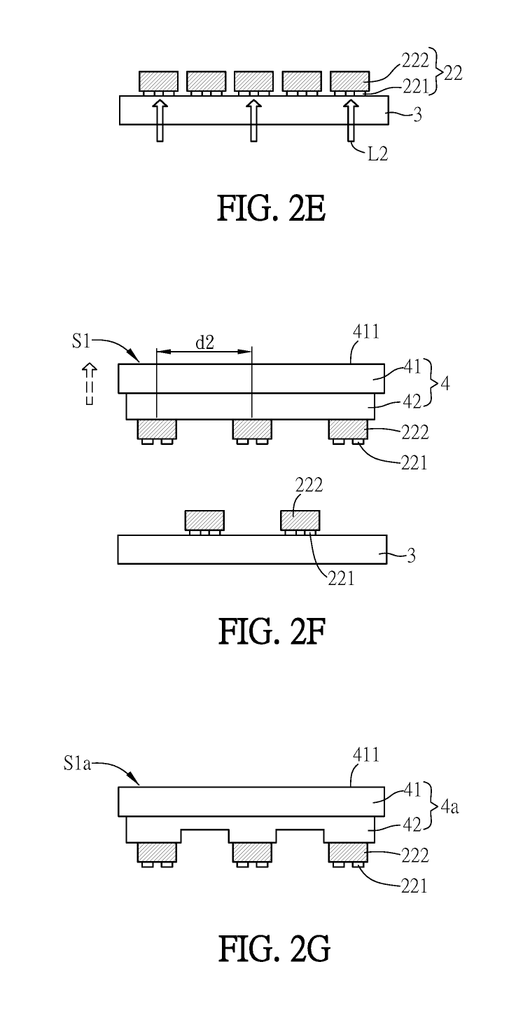

The detailed descriptions of the above steps will be illustrated hereinafter with reference to FIGS. 2A to 2F. FIGS. 2A to 2F are schematic diagrams showing the manufacturing procedures of an optoelectronic semiconductor stamp according to a first embodiment of this disclosure.

As shown in FIG. 1, the step S01 is to providing an optoelectronic semiconductor substrate. Referring to FIG. 2A, the optoelectronic semiconductor substrate 2 comprises an epitaxial substrate 21 and a plurality of optoelectronic semiconductor components 22. The optoelectronic semiconductor components 22 are separately disposed on the epitaxial substrate 21, and each of the optoelectronic semiconductor components 22 comprises at least an electrode 221. As shown in FIG. 2A, the optoelectronic semiconductor substrate 2 is reversed, which means that the epitaxial substrate 21 is disposed on the top and the electrode 221 faces downwardly. In this embodiment, each optoelectronic semiconductor component 22 comprises two electrodes 221 and one main body 222, and the main body 222 is disposed on the epitaxial substrate 21. The electrodes 221 are disposed on the surface of the main body 222 away from the epitaxial substrate 21. In this case, the optoelectronic semiconductor component 22 comprises flip-chip type electrodes or horizontal type electrodes. In other embodiments, the optoelectronic semiconductor component 22 may comprise vertical type electrodes, and this disclosure is not limited.

In some embodiments, the epitaxial substrate 21 can be a wafer plate, and can be made of transparent or opaque material, such as sapphire substrate, GaAs substrate or SiC substrate. In addition, the optoelectronic semiconductor components 22 can be arranged in an array (e.g. 2D array) and separately disposed on the epitaxial substrate 21. Alternatively, the optoelectronic semiconductor components 22 can be alternately arranged and separately disposed on the epitaxial substrate 21. This disclosure is not limited. Preferably, the optoelectronic semiconductor components 22 are arranged in a 2D array.

In this embodiment, the epitaxial substrate 21 is transparent sapphire substrate, and the material of the optoelectronic semiconductor components 22 is, for example but not limited to, GaN. In other embodiments, the material of the optoelectronic semiconductor components 22 can be other materials, such as AlGaAs, GaP, GaAsP, AlGaInP, or GaN. In addition, the optoelectronic semiconductor component 22 of this embodiment can be a blue LED chip, a green LED chip, a UV light LED chip, a laser LED chip, or a sensing chip (e.g. X-ray sensing chip). To be noted, the above-mentioned LED chip comprises a Mini LED chip or a Micro LED chip, and this disclosure is not limited. In general, the pitch of the optoelectronic semiconductor components 22 on the epitaxial substrate 21 is smaller. In this embodiment, a first pitch d1 is defined between adjacent two of the optoelectronic semiconductor components 22 on the optoelectronic semiconductor substrate 2. In some embodiments, the first pitch d1 is, for example but not limited to, 20 μm.

As shown in FIG. 2B, the step S02 is to press the optoelectronic semiconductor substrate 2 to an UV tape 3, wherein the electrodes 221 of the optoelectronic semiconductor components 22 are adhered to the UV tape 3. In this embodiment, the electrodes 221 face downwardly and are pressed on the UV tape 3, so that the UV tape 3 is adhered to the electrodes 221 of the optoelectronic semiconductor components 22.

Next, the step S03 is to remove the epitaxial substrate 21, wherein at least a part of the optoelectronic semiconductor components 22 are adhered to the UV tape 3. In this embodiment, before the step 03 of removing the epitaxial substrate 21, another step is needed to provide a light to irradiate a connection junction between the epitaxial substrate 21 and at least a part of the optoelectronic semiconductor components 22 (see FIG. 2C). Specifically, in order to remove the epitaxial substrate 21 and remain at least a part of the optoelectronic semiconductor components 22 on the UV tape 3, this embodiment is to provide a light to irradiate the connection junction between the epitaxial substrate 21 and all of the optoelectronic semiconductor components 22, thereby decreasing the adhesion between the epitaxial substrate 21 and all of the optoelectronic semiconductor components 22. For example, a laser (light L1) is inputted from one side of the optoelectronic semiconductor substrate 2 away from the UV tape 3 (upper side of the optoelectronic semiconductor substrate 2) to irradiate the connection junction between the epitaxial substrate 21 and all of the optoelectronic semiconductor components 22. The laser can provide energy to decompose the buffer layer (made of GaN) located at the connection junction between the material (GaN) of the optoelectronic semiconductor components 22 and the epitaxial substrate 21 (sapphire substrate), so that the optoelectronic semiconductor components 22 can be easily peeled off from the epitaxial substrate 21. In this embodiment, the non-selective laser lift off (LLO) technology is used to destroy the GaN buffer layer located at the connection junction of all optoelectronic semiconductor components 22, thereby decreasing the adhesion of all optoelectronic semiconductor components 22. As a result, the optoelectronic semiconductor components 22 can be easily peeled off from the epitaxial substrate 21.

After the step of providing a light to irradiate the connection junction between the epitaxial substrate 21 and all of the optoelectronic semiconductor components 22, since the GaN buffer layer located at the connection junction has been destroyed, all optoelectronic semiconductor components 22 can be remained (adhered) on the UV tape 3 (see FIG. 2D) after the following step S03 of removing the epitaxial substrate 21.

Next, the adhesion of at least a part of the UV tape 3 is decreased (step S04). As shown in FIG. 2E, the UV light (light L2) is provided to selectively irradiate a part of the UV tape 3 for curing the part of adhesive glue within the irradiated part, thereby selectively decreasing the adhesion of the UV tape 3. In this embodiment, the UV light is provided from one side of the UV tape 3 away from the optoelectronic semiconductor components 22 (the lower side of the UV tape 3) to irradiate alternate optoelectronic semiconductor components 22, thereby selectively curing a part of the adhesive glue of the UV tape 3. Since the part of adhesive glue irradiated by the UV light is cured and solidified, the adhesion between the optoelectronic semiconductor components 22 and the adhesive glue within the irradiated part can be decreased. As shown in FIG. 2E, the optoelectronic semiconductor components 22 corresponding to the irradiated part of the UV tape 3 are defined as one group. After repeating several times of step S04, a plurality of groups of optoelectronic semiconductor components 22 with decreased adhesion to the UV tape 3 can be provided for the following transferring process. Of course, it is also possible to provide all optoelectronic semiconductor components 22 with decreased adhesion to the UV tape 3 in one irradiation process (non-selective curing), and this disclosure is not limited.

Afterwards, as shown in FIG. 2F, the step S05 is performed to pick up at least a part of the optoelectronic semiconductor components 22 corresponding to the part of the UV tape 3 with reduced adhesion by a heat conductive substrate 4, wherein the part of the optoelectronic semiconductor components 22 corresponding to the part of the UV tape 3 with reduced adhesion is removed from the UV tape 3 so as to obtain the optoelectronic semiconductor stamp S1. The heat conductive substrate 4 comprises a buffer layer 42 disposed on a heat conductive base 41, and, in the step S05 of picking up the optoelectronic semiconductor components 22 corresponding to the part of the UV tape 3 with reduced adhesion, the buffer layer 42 of the heat conductive substrate 4 presses and adheres the optoelectronic semiconductor components 22. The material of the heat conductive base 41 comprises glass, metal, alloy, ceramics, or semiconductor material. The buffer layer 42 can have adhesion and be patterned or non-patterned. The adhesive material of the buffer layer 42 can be polydimethylsiloxane (PDMS), silica gel, thermal tape, or epoxy. The thickness of the buffer layer 42 can be, for example, less than 25 μm. Excepting the adhesion, the buffer layer 42 can also provide elasticity, so that the requirement for planar degree of the contact surface of the optoelectronic semiconductor components 22 and the target substrate of the following transferring process is not so critical.

In this embodiment, since the adhesion between the buffer layer 42 and a part of the optoelectronic semiconductor components 22 is greater than the adhesion between the optoelectronic semiconductor components 22 and the UV tape 3 (result of step S04), at least a part of the optoelectronic semiconductor components 22 corresponding to the part of the UV tape 3 with reduced adhesion can be departed from the UV tape 3 and picked up by the heat conductive substrate 4 after the heat conductive substrate 4 is removed from the UV tape 3. To be noted, the part of the optoelectronic semiconductor components 22 to be picked up by the heat conductive substrate 4 can be a part of the optoelectronic semiconductor components 22 corresponding to the part of the UV tape 3 with reduced adhesion or all of the optoelectronic semiconductor components 22 corresponding to the part of the UV tape 3 with reduced adhesion. The non-picked optoelectronic semiconductor components 22 can be remained on the UV tape 3. Accordingly, the optoelectronic semiconductor stamp S1 containing a plurality of optoelectronic semiconductor components 22 can be obtained.

As shown in FIG. 2F, the optoelectronic semiconductor stamp S1 of this embodiment can be manufactured by transferring at least a part of the optoelectronic semiconductor components 22 on the optoelectronic semiconductor substrate 2. In this embodiment, the optoelectronic semiconductor stamp S1 comprises a heat conductive substrate 4 and a plurality of optoelectronic semiconductor components 22 (which can be at least a part of the optoelectronic semiconductor components 22 on the optoelectronic semiconductor substrate 2) disposed on the heat conductive substrate 4. The optoelectronic semiconductor components 22 are indirectly disposed on the heat conductive substrate 4 via the adhesive function of the buffer layer 42.

In the optoelectronic semiconductor substrate 2, a first pitch d1 is defined between adjacent two of the optoelectronic semiconductor components 22 (FIG. 2A), and a second pitch d2 is defined between adjacent two of optoelectronic semiconductor components 22 of the optoelectronic semiconductor stamp S1 (FIG. 2F). The second pitch d2 is greater than or equal to the first pitch d1. The second pitch d2 is n times of the first pitch d1, and n is an integer greater than or equal to 1. In this embodiment, n is 2. To be noted, the term “pitch” is defined as the distance between the centers (or the left sides or the right sides) of two adjacent optoelectronic semiconductor components 22. In this embodiment, the second pitch d2 is twice of the first pitch d1 (n=2). Of course, in other embodiments, the second pitch d2 can also be 1 time, 3 times, 4 times, 5 times or more of the first pitch d1, and this can be determined based on the design requirement of the optoelectronic semiconductor device.

In addition, in the optoelectronic semiconductor stamp S1 of FIG. 2F, the surface of the buffer layer 42 of the heat conductive substrate 4 adhered to the optoelectronic semiconductor components 22 is a planar surface without pattern. In other embodiments, the surface of the buffer layer 42 adhered to the optoelectronic semiconductor components 22 can be a surface with a non-planar pattern.

FIG. 2G is a schematic diagram showing another optoelectronic semiconductor stamp according to the embodiment of this disclosure. In the optoelectronic semiconductor stamp S1a of FIG. 2G the buffer layer 42 of the heat conductive substrate 4a is configured with a pattern. In the heat conductive substrate 4a, the parts of the buffer layer 42 for adhering the optoelectronic semiconductor components 22 have a thicker thickness (protrusion), and the parts of the buffer layer 42, which do not adhere the optoelectronic semiconductor components 22, have a thinner thickness. In the step S05, the heat conductive substrate 4a can pick up at least a part of the optoelectronic semiconductor components 22 corresponding to the part of the UV tape 3 with reduced adhesion, so that the optoelectronic semiconductor components 22 corresponding to the part of the UV tape 3 with reduced adhesion can be departed from the UV tape 3 so as to obtain the optoelectronic semiconductor stamp S1a.

At least one of the optoelectronic semiconductor stamp S1 (or S1a) made by the above-mentioned method can be used to manufacturing an optoelectronic semiconductor device of this disclosure.

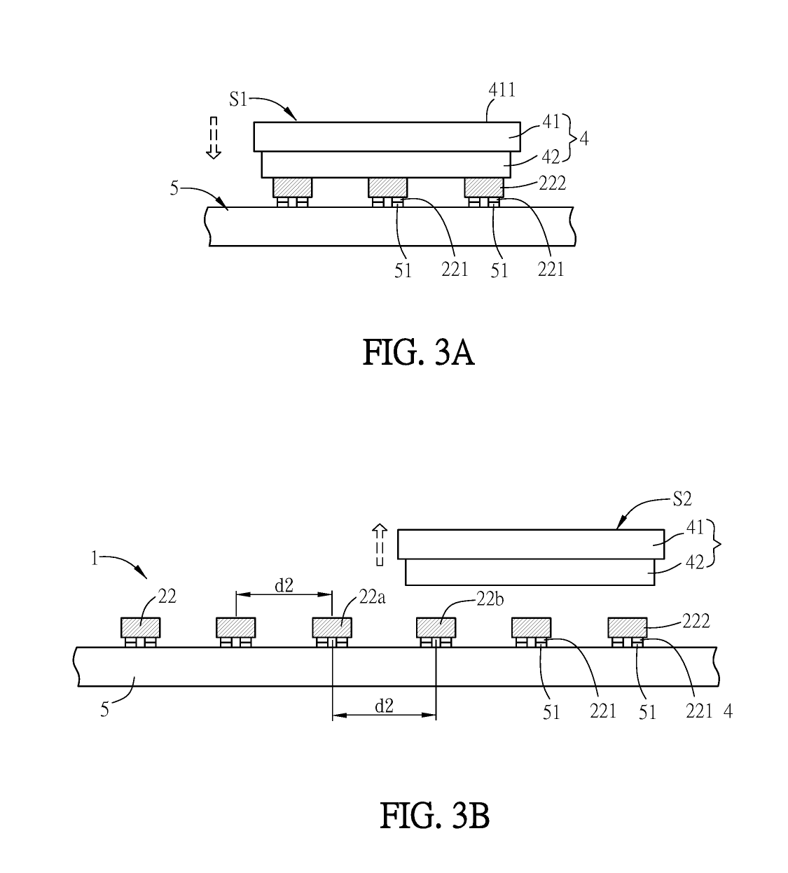

FIGS. 3A and 3B are schematic diagrams showing the manufacturing procedure of an optoelectronic semiconductor device according to an embodiment of this disclosure. Taking the optoelectronic semiconductor stamp S1 as an example, referring to FIG. 3A, after the optoelectronic semiconductor stamp S1 is pressed on a target substrate 5, and then the electrodes 221 of the optoelectronic semiconductor components 22 on the optoelectronic semiconductor stamp S1 are electrically connected with the corresponding electrical conductive portions 51 of the target substrate 5. In this embodiment, the target substrate 5 comprises a plurality of electrical conductive portions 51, and the electrical conductive portions 51 are disposed corresponding to the electrodes 221 of the optoelectronic semiconductor components 22. In some embodiments, the optoelectronic semiconductor stamp S1 is picked up (by grabbing or sucking) from one side (surface 411) of the heat conductive base 41 away from the optoelectronic semiconductor components 22. In some embodiments, the thermal conductivity of the heat conductive substrate 4 (or heat conductive base) can be greater than 1 W/mK. Accordingly, a bonding machine (e.g. a ball bonder) can be used to grab or suck the heat conductive substrate 4 and to heat the heat conductive substrate 4. Then, the heat can be transmitted through the heat conductive substrate 4 for heating the electrodes 221 of the optoelectronic semiconductor components 22 on the heat conductive substrate 4, thereby electrically connecting the electrodes 221 to the corresponding electrical conductive portions 51 by eutectic bonding. Since the adhesion of the buffer layer 42 can be decreased at high temperature, the step of heating the heat conductive substrate 4 can facilitate the bonding of the optoelectronic semiconductor components 22 on the optoelectronic semiconductor stamp S1 and the electrical conductive portions 51 of the target substrate 5. Accordingly, this process can make the optoelectronic semiconductor components 22 be easily departed from the heat conductive substrate 4. Then, the heat conductive substrate 4 can be removed.

Excepting the eutectic bonding, in other embodiments, after picking up the optoelectronic semiconductor stamp S1 from the side of the heat conductive base 41 away from the optoelectronic semiconductor components 22 and pressing the optoelectronic semiconductor stamp S1 on the target substrate 5, the electrodes 221 of the optoelectronic semiconductor components 22 can be electrically connected with the corresponding electrical conductive portions 51 by anisotropic conductive film (ACF, not shown). Afterwards, the heat conductive substrate 4 can be removed. This disclosure is not limited.

When the bonder picks up and heats the heat conductive substrate 4, the bonding force between the electrical conductive portions 51 and the electrodes 221 of the optoelectronic semiconductor components 22 (or the bonding force between the electrodes 221 and the ACF) is greater than the adhesion between the buffer layer 42 and the optoelectronic semiconductor components 22, so that the heat conductive substrate 4 can be easily removed, and the optoelectronic semiconductor components 22 can be remained on the target substrate 5 and electrically connected with the electrical conductive portions 51 of the target substrate 5. Accordingly, after the electrical connection bonding and removing the heat conductive substrate 4, the target substrate 5 containing a plurality of optoelectronic semiconductor components 22 can be manufactured (see FIG. 3B).

To be noted, the above embodiment is to electrical connect the electrodes 221 with the corresponding electrical conductive portions 51 (by eutectic bonding or ACF) before removing the heat conductive substrate 4, but this disclosure is not limited thereto. In other embodiments, an adhesive layer (not shown) can be applied on the target substrate 5, and the adhesion between the adhesive layer and the optoelectronic semiconductor components 22 is greater than the adhesion between the optoelectronic semiconductor components 22 and the heat conductive substrate 4. Accordingly, after picking up the optoelectronic semiconductor stamp S1 and adhering the electrodes 221 of the optoelectronic semiconductor components 22 to the adhesive layer, the heat conductive substrate 4 is removed, and then the electrodes 221 of the optoelectronic semiconductor components 22 are electrically connected with the corresponding electrical conductive portions 51 by eutectic bonding or anisotropic conductive film (ACF). This disclosure is not limited.

In some embodiments, the target substrate 5 can be made of a transparent material, such as glass, quartz or the likes, plastics, rubber, glass fiber, or other polymer materials. In some embodiments, the target substrate 5 can be made of opaque materials, such as a metal-glass fiber composition plate, or a metal-ceramics composition plate. In addition, the target substrate 5 can be a rigid plate or a flexible plate, and this disclosure is not limited. In some embodiments, the target substrate 5 comprises a matrix circuit (not shown, the matrix circuit comprises the electrical conductive portions 51 arranged in an array). According to the circuit type, the matrix circuit can be an active matrix (AM) circuit or a passive matrix (PM) circuit. In some embodiments, the target substrate 5 can be a thin-film transistor (TFT) substrate. The TFT substrate is configured with thin-film components (e.g. thin-film transistors) and thin-film circuits. For example, the TFT substrate can be an AM TFT substrate or a PM TFT substrate. For example, the AM substrate (AM TFT substrate) comprises a matrix circuit containing interlaced data lines and scan lines and a plurality of thin-film transistors. Since the AM substrate or PM substrate can be easily understood by the skilled person in the art and is not the key point of this disclosure, so the detailed description thereof will be omitted.

Afterwards, the pressing step is repeated as shown in FIG. 3B. After pressing another optoelectronic semiconductor stamp S2 on the target substrate 5, the electrodes 221 of the optoelectronic semiconductor components 22 of the optoelectronic semiconductor stamp S2 are electrically connected with the corresponding electrical conductive portions 51 of the target substrate 5. Accordingly, the optoelectronic semiconductor device 1 can be obtained.

To be noted, during manufacturing process of the optoelectronic semiconductor stamp S2, the step S04 of decreasing the adhesion of at least a part of the UV tape 3 (see FIG. 2E) is to move the UV light (light L2) irradiated positions by, for example, a first pitch d1, wherein the UV tape 3 is remained at the original position (the UV tape 3 is not moved). In addition, when electrically bonding the optoelectronic semiconductor stamp S2 to the target substrate 5, the target substrate 5 is not moved, and the optoelectronic semiconductor stamp S2 is moved by a pitch (e.g. the second pitch d2). Accordingly, a plurality of optoelectronic semiconductor components 22 of the optoelectronic semiconductor stamp S2 can be disposed corresponding to the adjacent positions of the optoelectronic semiconductor components 22 of the optoelectronic semiconductor stamp S1, which have been transferred to the target substrate 5. Therefore, regarding two adjacent optoelectronic semiconductor components 22 on the target substrate 5, as shown in FIG. 3B, if one of the optoelectronic semiconductor components 22 (e.g. an optoelectronic semiconductor component 22a) is from the optoelectronic semiconductor stamp S1, the other optoelectronic semiconductor component (e.g. an optoelectronic semiconductor component 22b) is from the optoelectronic semiconductor stamp S2, and the pitch between the two adjacent optoelectronic semiconductor components is still the second pitch d2.

In addition, the two adjacent optoelectronic semiconductor components 22 from the optoelectronic semiconductor stamp S1 have a second pitch d2, so that the two adjacent optoelectronic semiconductor components 22 disposed on the target substrate also have a second pitch d2. The two adjacent optoelectronic semiconductor components 22 from the optoelectronic semiconductor stamp S2 have a second pitch d2, so that the two adjacent optoelectronic semiconductor components 22 disposed on the target substrate also have a second pitch d2. Moreover, as shown in FIG. 3B, the pitch between the leftmost optoelectronic semiconductor component (22b) from the optoelectronic semiconductor stamp S2 and the rightmost optoelectronic semiconductor component (22a) from the optoelectronic semiconductor stamp S1 can be a second pitch d2 based on the design requirement. Of course, the pitch between the optoelectronic semiconductor component (22b) and the optoelectronic semiconductor component (22a) can be not equal to the second pitch d2 based on the design requirement. Of course, the pitch between the two optoelectronic semiconductor components can be approximated to the second distance d2 but not equal to the second distance d2 due to the process accuracy.

As shown in FIG. 3B, adjacent two optoelectronic semiconductor components (e.g. 22a and 22b) on the target substrate 5 of the optoelectronic semiconductor device 1 can be defined in one pixel or different pixels. In addition, the optoelectronic semiconductor component 22 from the optoelectronic semiconductor stamp S1 and the optoelectronic semiconductor component 22 from the optoelectronic semiconductor stamp S2 can emit the same color lights or different color lights, or can be the same kinds or types of optoelectronic semiconductor components or different kinds or types of optoelectronic semiconductor components. This disclosure is not limited. If the optoelectronic semiconductor component 22 from the optoelectronic semiconductor stamp S1 and the optoelectronic semiconductor component 22 from the optoelectronic semiconductor stamp S2 can emit the same color lights, the optoelectronic semiconductor device 1 can be a monochromatic LED display device. If the optoelectronic semiconductor component 22 from the optoelectronic semiconductor stamp S1 and the optoelectronic semiconductor component 22 from the optoelectronic semiconductor stamp S2 can emit different color lights, the optoelectronic semiconductor device 1 can be a full-color LED display device having, for example, red, green and blue pixels. This disclosure is not limited.

For example, in order to manufacturing an AM LED display device, only the bonding machine (e.g. a flip-chip bonding machine or a die bonding machine) in cooperate with the eutectic bonding process or ACF bonding process is required for transferring and combining a plurality of optoelectronic semiconductor components (LEDs) from the optoelectronic semiconductor stamp to the TFT substrate (target substrate) based on the required size or shape, thereby finishing the manufacturing of the AM LED display device.

As mentioned above, the optoelectronic semiconductor device 1 of this embodiment can be manufactured by transferring a plurality of optoelectronic semiconductor components 22 from the optoelectronic semiconductor substrate 2. In one embodiment, a plurality of optoelectronic semiconductor components 22 are transferred from at least one optoelectronic semiconductor stamp to the target substrate 5 so as to obtain the optoelectronic semiconductor device 1. In other words, the optoelectronic semiconductor components 22 are batch transferred from the optoelectronic semiconductor stamp S1 to the target substrate 5 and then combined to fabricate the optoelectronic semiconductor device 1 of the desired size and shape. As shown in FIG. 3B, the optoelectronic semiconductor device 1 of this embodiment comprises a target substrate 5 and a plurality of optoelectronic semiconductor components 22 from the optoelectronic semiconductor stamps (S1 and S2), and the electrodes 221 of the optoelectronic semiconductor components 22 are electrically connected with the corresponding electrical conductive portions 51 of the target substrate 5. In some embodiments, the electrodes 221 can be electrically connected with the corresponding electrical conductive portions 51 by eutectic bonding or ACF bonding. In addition, the second pitch d2 between two adjacent optoelectronic semiconductor components 22 on the target substrate 5 can be greater than or equal to the first pitch d1 between two adjacent optoelectronic semiconductor components 22 on the optoelectronic semiconductor stamps. The second pitch d2 is n times of the first pitch d1, and n is an integer greater than or equal to 1. In some embodiments, the optoelectronic semiconductor device 1 can be an LED display device, a light sensing device, or a laser array. In this embodiment, the LED display device also comprises a Mini LED display device or a Micro LED display device.

In some embodiments, the optoelectronic semiconductor components on the heat conductive substrate of the optoelectronic semiconductor stamp (S1 or S2) can be arranged in a polygon shape, such as, for example but not limited to, a triangle, a square, a diamond, a rectangle, a trapezoid, a parallelogram, a hexagon, or an octagon, . . . or other shapes. Accordingly, the required optoelectronic semiconductor components 22 can be transferred from the optoelectronic semiconductor stamps (S1 and/or S2) to the target substrate 5 and then combined to obtain the optoelectronic semiconductor device in the desired shape (e.g. a rectangle). This configuration can increase the total utility rate of the circular wafer.

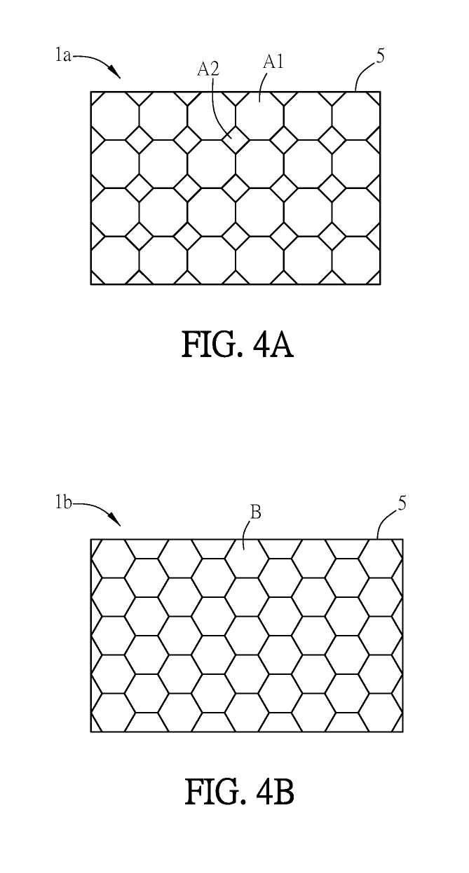

FIGS. 4A and 4B are schematic diagrams showing the combined shapes of the optoelectronic semiconductor devices 1a and 1b according to different embodiments of this disclosure. As shown in FIGS. 4A and 4B, a plurality of optoelectronic semiconductor stamps are transferred to and combined on the target substrate 5, and the target substrate 5 is correspondingly covered by a plurality of optoelectronic semiconductor stamps, thereby forming a rectangular display device. The stamp covering range is the arranging shape of the optoelectronic semiconductor components on the heat conductive substrate of the optoelectronic semiconductor stamp, and the stamp covering range can be a polygonal shape. In the optoelectronic semiconductor device 1a of FIG. 4A, the stamp covering range A1 on the target substrate 5 is an octagon, and the stamp covering range A2 on the target substrate 5 is a diamond. In the optoelectronic semiconductor device 1b of FIG. 4B, the stamp covering range B on the target substrate 5 is a hexagon. This disclosure is not limited thereto. In other embodiments, the stamp covering range can be designed as other shapes, such as a square, a rectangle, a trapezoid, a parallelogram, a circle, . . . or other shapes depending on the design requirement. In addition, the stamp covering range of a later pressing process can cover (or partially overlap) at least one of the stamp covering ranges of the previous pressing processes. Alternatively, the stamp covering range of a later pressing process can not cover (or not overlap) at least one of the stamp covering ranges of the previous pressing processes. This disclosure is not limited.

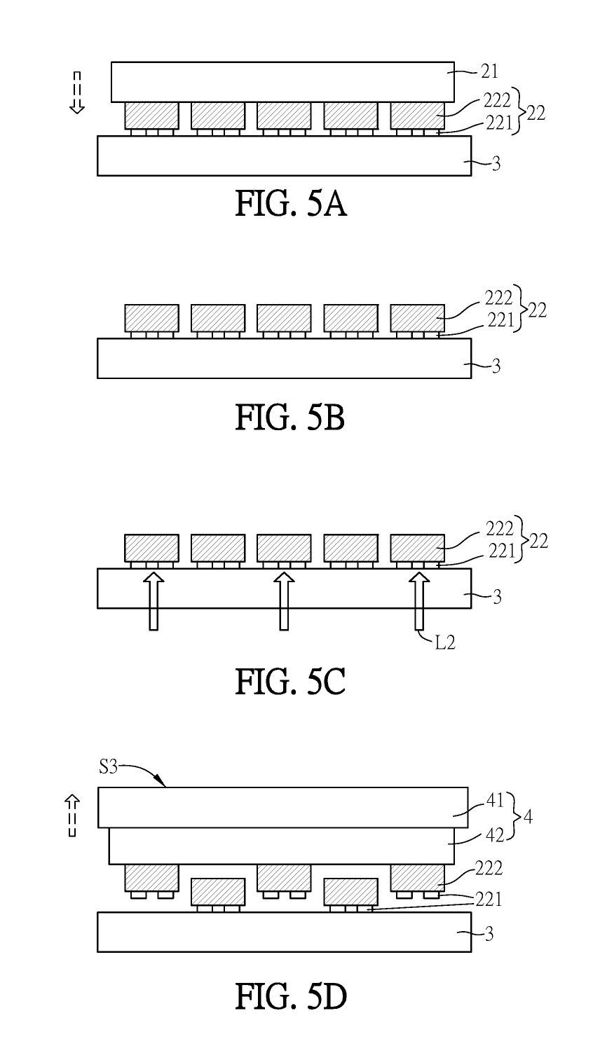

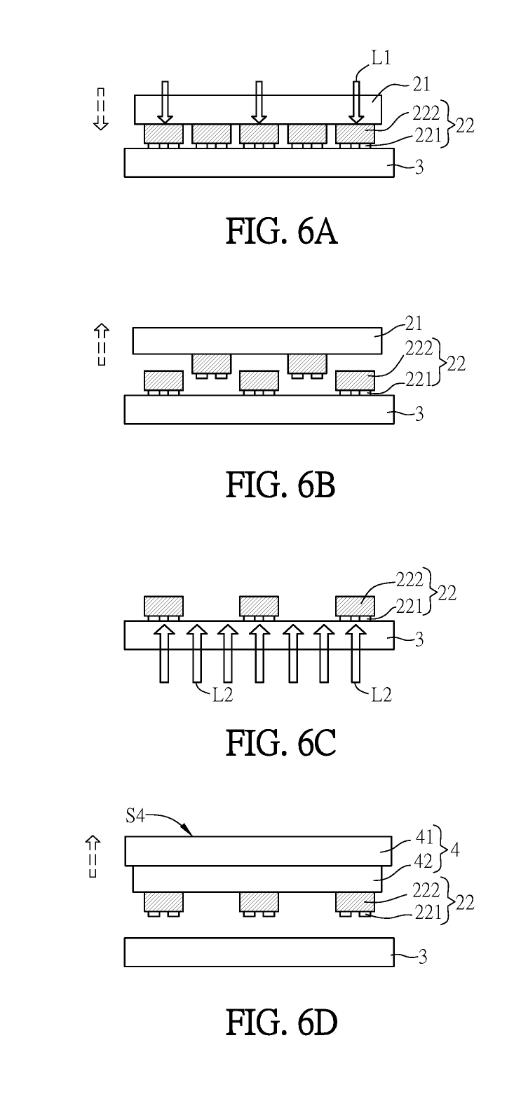

FIGS. 5A to 5D are schematic diagrams showing the manufacturing procedures of an optoelectronic semiconductor stamp S3 according to a second embodiment of this disclosure, and FIGS. 6A to 6D are schematic diagrams showing the manufacturing procedures of an optoelectronic semiconductor stamp S4 according to a third embodiment of this disclosure.

Different from the first embodiment, in the second embodiment as shown in FIGS. 5A to 5D, the epitaxial substrate 21 is a GaAs substrate, and the optoelectronic semiconductor components 22 can be red LED chips, yellow LED chips, laser LED chips, sensing chips, or IR chips. In addition, as shown in FIGS. 5A and 5B, the step S03 of removing the epitaxial substrate 21 is to directly remove the epitaxial substrate 21 by an etching process (wet etching process) or a polishing process. The other steps of the manufacturing method of the optoelectronic semiconductor stamp S3 of the second embodiment are the same as the first embodiment, so the detailed descriptions thereof will be omitted.

Different from the first embodiment, in the third embodiment as shown in FIGS. 6A to 6D, before the step S03 of removing the epitaxial substrate 21, a light is provided to irradiate the connection junction between the epitaxial substrate 21 and a part of the optoelectronic semiconductor components 22 (selective laser lift off (LLO) technology). For example, the optoelectronic semiconductor components 22 are alternately irradiated by the light. Afterwards, in the step S03 of removing the epitaxial substrate 21, as shown in FIG. 3B, a part of the optoelectronic semiconductor components 22, which are not irradiated by the light L1, can be remained on the epitaxial substrate 21, and the other optoelectronic semiconductor components 22, which are irradiated by the light L1, can be remained on the UV tape 3 after removing the epitaxial substrate 21. In addition, as shown in FIG. 6C, this embodiment is to provide non-selective UV light (light L2) to irradiate the UV tape 3 for curing the adhesive glue of the UV tape 3. Accordingly, the adhesion between all optoelectronic semiconductor components 22 and the UV tape 3 can be decreased. The other steps of the manufacturing method of the optoelectronic semiconductor stamp S4 of the third embodiment are the same as the first embodiment, so the detailed descriptions thereof will be omitted.

In summary, the manufacturing method of the optoelectronic semiconductor stamp comprises steps of: pressing the optoelectronic semiconductor substrate to an UV tape; removing the epitaxial substrate, so that at least a part of the optoelectronic semiconductor components are adhered to the UV tape; decreasing adhesion of at least a part of the UV tape; and picking up at least a part of the optoelectronic semiconductor components corresponding to the part of the UV tape with reduced adhesion by a heat conductive substrate. The part of the optoelectronic semiconductor components corresponding to the part of the UV tape with reduced adhesion is removed from the UV tape so as to obtain the optoelectronic semiconductor stamp. Then, at least one optoelectronic semiconductor stamp can be transferred to the target substrate, or a plurality of optoelectronic semiconductor stamps can be combined and transferred to the target substrate, thereby obtaining the optoelectronic semiconductor device. Compared with the conventional manufacturing processes of optoelectronic device made of LEDs, which is to perform the epitaxial process, the photolithograph process, and the cutting processes (including half-cut, point measurement and full-cut processes) to obtain the individual optoelectronic semiconductor components, this disclosure does not need to transfer the optoelectronic semiconductor components to the target substrate one by one. As a result, this disclosure has the advantages of simple processes and short manufacturing time. Besides, this disclosure can achieve the goal of batch transferring, so that the optoelectronic semiconductor device can have shorter manufacturing time and lower cost.

Although the disclosure has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the disclosure.

What is claimed is:

1. A manufacturing method of an optoelectronic semiconductor stamp, comprising steps of:
providing an optoelectronic semiconductor substrate, wherein the optoelectronic semiconductor substrate comprises a plurality of optoelectronic semiconductor components separately disposed on an epitaxial substrate, and each of the optoelectronic semiconductor components comprises at least an electrode;
pressing the optoelectronic semiconductor substrate to an UV tape, wherein the electrodes of the optoelectronic semiconductor components are adhered to the UV tape;
removing the epitaxial substrate, wherein at least a part of the optoelectronic semiconductor components are adhered to the UV tape;
decreasing adhesion of at least a part of the UV tape; and
picking up at least a part of the optoelectronic semiconductor components corresponding to the part of the UV tape with reduced adhesion by a heat conductive substrate, wherein the part of the optoelectronic semiconductor components corresponding to the part of the UV tape with reduced adhesion is removed from the UV tape so as to obtain the optoelectronic semiconductor stamp, the heat conductive substrate comprises a buffer layer disposed on a heat conductive base, and the buffer layer adheres the optoelectronic semiconductor components corresponding to the part of the UV tape with reduced adhesion.

2. The manufacturing method according to claim 1, before the step of removing the epitaxial substrate, further comprising:
providing a light to irradiate a connection junction between the epitaxial substrate and at least a part of the optoelectronic semiconductor components.

3. The manufacturing method according to claim 1, wherein the step of removing the epitaxial substrate is to remove the epitaxial substrate by an etching process or a polishing process.

4. The manufacturing method according to claim 1, wherein a first pitch is defined between adjacent two of the optoelectronic semiconductor components on the optoelectronic semiconductor substrate, a second pitch is defined between adjacent two of optoelectronic semiconductor components of the optoelectronic semiconductor stamp, and the second pitch is greater than or equal to the first pitch.

5. The manufacturing method according to claim 4, wherein the second pitch is n times of the first pitch, and n is an integer greater than or equal to 1.

6. An optoelectronic semiconductor stamp, comprising:
a heat conductive substrate comprising a heat conductive base and a buffer layer, wherein the buffer layer is disposed on the heat conductive base; and
a plurality of optoelectronic semiconductor components adhered to the heat conductive base through the buffer layer, wherein the optoelectronic semiconductor components are separately disposed on the heat conductive substrate;
wherein the optoelectronic semiconductor stamp is formed by transferring at least a part of optoelectronic semiconductor components from an optoelectronic semiconductor substrate to the heat conductive substrate.

7. The optoelectronic semiconductor stamp according to claim 6, wherein a first pitch is defined between adjacent two of the optoelectronic semiconductor components on the optoelectronic semiconductor substrate, a second pitch is defined between adjacent two of optoelectronic semiconductor components of the optoelectronic semiconductor stamp, and the second pitch is greater than or equal to the first pitch.

8. The optoelectronic semiconductor stamp according to claim 7, wherein the second pitch is n times of the first pitch, and n is an integer greater than or equal to 1.

9. The optoelectronic semiconductor stamp according to claim 6, wherein the optoelectronic semiconductor components on the heat conductive substrate are arranged in a polygon.

10. An optoelectronic semiconductor device, comprising:
a target substrate having a plurality of electrical conductive portions; and
a plurality of optoelectronic semiconductor components comprising a plurality of electrodes, wherein the electrodes are disposed corresponding to and electrically connected to the electrical conductive portions;
wherein the optoelectronic semiconductor device is formed by transferring the optoelectronic semiconductor stamp of claim 6 to the target substrate.

11. The optoelectronic semiconductor device according to claim 10, wherein after the optoelectronic semiconductor stamp is pressed on the target substrate, the heat conductive base is heated to electrically connect the electrodes of the optoelectronic semiconductor components and the corresponding electrical conductive portions by eutectic bonding, and then the heat conductive substrate is removed.

12. The optoelectronic semiconductor device according to claim 10, wherein after the optoelectronic semiconductor stamp is pressed on the target substrate, the electrodes of the optoelectronic semiconductor components are electrically connected with the corresponding electrical conductive portions by anisotropic conductive film (ACF), and then the heat conductive substrate is removed.

13. The optoelectronic semiconductor device according to claim 10, wherein after the optoelectronic semiconductor stamp is pressed on the target substrate, the heat conductive substrate is removed, and then the electrodes of the optoelectronic semiconductor components are electrically connected with the corresponding electrical conductive portions by eutectic bonding.

14. The optoelectronic semiconductor device according to claim 10, wherein after the optoelectronic semiconductor stamp is pressed on the target substrate, the heat conductive substrate is removed, and then the electrodes of the optoelectronic semiconductor components are electrically connected with the corresponding electrical conductive portions by anisotropic conductive film (ACF).

15. The optoelectronic semiconductor device according to claim 10, wherein the optoelectronic semiconductor components on the heat conductive substrate of the optoelectronic semiconductor stamp are arranged in a polygon.

16. The optoelectronic semiconductor device according to claim 10, wherein the optoelectronic semiconductor device is a LED display device, a light sensing device, or a laser array.
